(19) United States
(12) Patent Application Publication
(10) Pub. No.: US 2009/0229650 A1
(43) Pub. Date: Sep. 17, 2009

(54) Solar thermoelectric power station

(76) Inventors: Jon Murray Schroeder, Cedar Park, TX (US); Gerald Philip Hirsch, Clarksville, TN (US)

Correspondence Address: Jon Murray Schroeder, 3501 CR 279, Leander, TX, 78641, US

(21) Appl. No.: 12/454,379

(22) Filed: May 18, 2009

Related U.S. Application Data
(63) Continuation-in-part of application No. 10/340,885, filed on Jan. 13, 2003, now abandoned.
(60) Provisional application No. 61/198,571, filed on Nov. 7, 2008.

(51) Int. Cl. H01L 35/00; F24J 2/34

(52) U.S. Cl. 136/206; 126/617

(57) ABSTRACT

A solid-state thermoelectric generator device can directly drive a high voltage grid at voltage without a special step-up transformer. Phase sensing, output voltage and waveform of the generator can be electronically adjusted to match parameters sensed directly from the grid, generator output adjusted to conform exactly to the grid. Three solar powered generators connected as a “y” with three legs with common earth grounds can power individual phases of the grid as a mini-power plant providing three-phase grid voltage electricity. Power quality correction to the grid can be made to individual phases of the grid on an automatic, self-correcting basis as needed.

### RELATED APPLICATIONS

This application claims priority data of provisional application 61/198,571 filed 7 Nov. 2008. This application contains improvements to pending U.S. patent application Ser. No. 10/154,757, filed May 23, 2002, entitled “Torus Semiconductor Thermoelectric Device” published Nov. 27, 2003.” It also contains improvements to pending U.S. patent application Ser. No. 11/259,922, filed Oct. 28, 2005, entitled “Solid state thermoelectric power converter” non-publication request. It also contains improvements to pending U.S. patent application Ser. No. 11/517,882, filed Sep. 8, 2006, entitled “Thermoelectric device with make-before-break high frequency converter” non-publication request. It also contains improvements to pending U.S. patent application number CIP of application Ser. No. 10/340,885, filed Sep. 8, 2006, entitled “Bismuth-Tellurium and Antimony-Telluride-Based Thermoelectric Chiller” non-publication.

### TECHNICAL FIELD

This invention relates to a way to generate renewable energy close to a power grid, place power on the grid where it is needed to support electrical loads for the local needs rather than make electricity in one part of the state and transport it to another. The invention described herein allows for 19.9-megawatt packets of power production to be placed adjacent to or even under the power transmission grid, energizing transmission lines where needed most. The invention uses a solar, or gas, powered thermal-to-electric generator to provide a portion of the electrical needs of the nation day and night, without carbon emission or total reliance on intermittent wind power. Thermal-to-electric generators are quiet, vibration-free, and use stored solar heat to operate daytime and nighttime.

Like highways and bridges, the distribution grid utilized by electricity producers and consumers is a vast and important component of America's infrastructure. Also like highways and bridges, it is expensive and sometimes difficult to maintain; a large part of the nation's wealth is vested in the electric power grid that supplies industrial, institutional, residential and commercial properties across the land. This nation depends on the electric grid, perhaps even more so than its highways. Part of the struggle for the grid to supply power to those who need it involves the nature of how it was developed and how it is currently utilized. The vast majority of power is generated by large power plants of 250 megawatts or more, some as much as 750 megawatts. These plants must transmit power long distances over the grid and various factors result in loss and waste. Temperature changes and peak loading contribute to brown outs and blackouts; lines are vulnerable to environmental exposure. Further, it is an expensive and time-consuming process to bring new large power plants online. Few people wish to live near one, particularly if coal or nuclear fuels are used. If a new plant does get built, it is usually well away from existing transmission lines, which means new cable must be laid underground or strung from towers and poles, right-of-way must be acquired, other parts of the existing infrastructure must be upgraded. All of this comes at great expense, both monetary and in negative public opinion. Take this example: September 2008 the Public Utilities Commission of Texas approved a 130-mile transmission line project in Williamson County. This project is a joint venture between the Lower Colorado River Authority (LCRA) and Oncor Electric Delivery Co. LLC. Together they will put in place a high-tension line carrying 345,000 volts, the second for that general area. The estimated cost: $2,192,000 per mile—this is just for transmission capacity. And many residents are unhappy, citing safety and esthetic concerns over power lines and switching stations. Add to the above the standard problems that new and existing large power generators and distributors face, stranded assets. Stranded assets are capital investments, power purchase contracts, fuel supply contracts, and other regulatory assets, the cost of which are not expected to be recovered through the sale of competitively priced electricity. The magnitude of stranded assets and who should bear the costs are contentious issues at the core of regulatory/legislative proceedings aimed at evolving competitive electricity markets. For example, on the issue of cost allocation, the California Legislature and the Public Utilities Commission (CPUC) recently have “set a precedent, essentially ruling that the California ratepayers will incur one hundred percent of the stranded asset costs and will [assess] non-by-passable competitive transition charges on ratepayers”.

The invention allows for seamless transition of power to the distribution grid, providing three-phase electricity by using three single-phase generator legs, which are automatically self-correcting for line-voltage, phase and waveform quality.

This grid feeder invention allows power for an industry, institution or housing development to be produced away from the point of electrical power production, transported over the grid seamlessly to the point of use, surplus power to be used by other users of the grid for revenue.

This invention allows electrical power produced remotely to be used to heat a heat store equipped with an onsite generator, the onsite generator can power the site using only stored heat for a number of days, using only the heat energy from the heat store. In this way, solar heat collection is performed remotely and electrically heating of the high mass heat store driving the generator, installed in the basement, flowerbed or rooftop of a facility located in a congested area. Heat stores with generators can be charged electrically at zero cost to indigent consumers. Consumer locations without the space required for onsite solar heat collection, such as in densely populated city dwellings, can be re-charged in this way.

### BACKGROUND ART

This invention applies to electric generation for the nation's utility grid and also for home, industry and institution. The utility grid that powers home and industry in the U.S. has huge capacity and spinning reserve. On the other hand, electrical loads in homes, industry and institutions are constantly changing, powered by large electric generating plants located large distances from populations. These large plants have trouble adapting to ever changing loads and this is the reason large (and wasteful) spinning loads are required to quickly adapt to these changing loads. The generator(s) of this invention are small, 333-kW/single and 3-phase compared to a typical 500-MW coal-fired plant, which is huge and power from these plants must be transformed in voltage to be useful on the grid, then transformed again to be useful to the consumer. The smaller generators of this invention are dedicated to powering individual customers or individual phases of the grid. Solid state generators are mounted directly on insulated heat storage vessel with a solar collector also mounted on the store. The largest generator we build at this time is a less than 0.333-megawatt so they are configured as either 3-phase, or as single phase grid driver generating stations so that they can directly drive a single leg of a high voltage grid. A group of thee single phase generators can operate as a 1-megawatt system, twenty-two of these devices used to configure and power a 20-megawatt station that can connect to the grid unregulated at this time. A unique aspect of our solar heat store-powered station is; this system is configured to continually sample each leg of the grid it helps to power, making minute electronic adjustments to mimic exactly the generator's output as to the grid's frequency, wave form and operating voltage. Should the grid's waveform have errors or be out of form, errors are corrected by adjusting the waveforms injected into the grid by any or all of the single-phase generators. In this way, quality of the grid can be restored and maintained by arrays of small generators. By using sets of three, heat store-generator power stations, they can inject electrical energy power into each of the three phases of the grid operating with electrical outputs up to 345,000 volt. The output of the generators can be configured to match exactly the particular grid voltage it services. This means a solar heat operated generator station will not require a multi-million dollar step-up transformer to service the existing grid. Also, when step-up transformers go down, repair is costly and time consuming. Three of the 333-kW power, single-phase stations can place 1-megawatt on the grid powering the three individual and different phases. Twenty-two of the 1-MW, 3-phase units can place 20-MWs of electrical power on the grid on an around the clock basis, taking advantage of each of the large capacity heat stores driving individual solid state generators. This invention will benefit the utility user, as well as the nation as a whole with a plentiful supply of zero cost electricity derived from the sun, installed exactly where it is needed or at least close in on the transmission grid.

### RELATED PATENTS

U.S. Pat. No. 6,222,242 to Konishi, et al., discloses semiconductor material of the formula AB sub.2, Xsub.4 where A is one of or a mixture of Pb, Sn, or Ge, B is one of a mixture of Bi and Sb and X is one of or a mixture of Te and Se. These represent Pb, Sn or Ge doped bismuth telluride.

U.S. Pat. No. 6,274,802 to Fukuda, describes a sintering method of making semiconductor material whose principle components include bismuth, tellurium and selenium and antimony.

U.S. Pat. No. 6,304,787 to Simeray describes a thermoelectric component of bismuth doped with antimony and bismuth telluride doped selenium wherein said component is arranged into a rod. Very low voltages are converted using self-oscillating circuit.

U.S. Pat. No. 6,172,427 describes the use of a thermoelectric device on the exhaust portion of a combustion-based car using electrically driven wheel wherein excess heat energy is converted to electric power for the vehicle.

It is a purpose of this invention to provide improved efficiency for the solar heat conversion to electrical energy by solid state to drive the transmission grid injecting single and 3-phase power to the grid directly without a need for a step-up transformer.

It is a further purpose of this invention that no carbon emissions occur from solar-electric power plants used to help drive the electric grid.

It is a further purpose that electricity for the grid can be produced without the burning of coal, imported oil and natural gas.

It is a further purpose of this invention that no fuel costs occur with solar heat powered generators, only the maintenance costs for occasional collector cleaning.

It is a further purpose of this invention that electricity produced from stored solar heat can be used to backstop windmills, increasing on-line reliability for windmill forms of renewable energy and solar-voltaic electrical energy.

It is a further purpose that solar electric power can be produced offsite, then electricity piped over the grid to specific plant location where electricity is needed to allow this system to operate as both a generator, electrical storage system and low cost electrical distributor.

It is a further purpose of this invention to use offsite solar electric plants to deliver electric service over the grid to power onsite heat-storing generator sets, that can essentially store electricity using stored heat energy from grid heating when electrical surpluses occur to allow solid state electric generators to produce electricity from this long term heat store. By making use of grid heating of the store, with the generator operating from the heat store to produce electricity when the grid is down, electrical energy can be given back when grid is low in capacity or at times when grid is grossly overloaded.

It is a further purpose of this invention to use onsite heat storage and electric generator systems, powered by an offsite solar electric system, the onsite generator system configured to power solid state refrigeration, for environmental air conditioning and heating, to liquefy oxygen, nitrogen and carbon dioxide condensed from the atmosphere if needed for plant usage. Also, the combined system can provide a supply of hot water using waste heat for heating processes in the plant requiring no onsite solar collection. Further more, use can be made of waste heat from electric generation for drying and heating operations in the plant. The harvesting of water from the atmosphere at nighttime is made practical with low cost, dependable electricity and efficient solid-state refrigeration.

It is a further purpose of this invention to power and re-fuel with heat, fleets of NAFTA trucks hauling between Mexico City to Montreal so heat stores topped off at reheating truck stop stations along IH-35 and other interstate highways, using grid feeder electric heating from onsite stores, the grid feeding from solar electric grid reheating stations located near the grid anywhere along the NAFTA routes, with grid electricity produced by solar collection stations near the borders. With this concept, long-haul trucks that now require expensive diesel fuel derived from imported oil can make use of sunshine produced heat-to-electricity feeding into the grid from anywhere the sun shines brightly. The electrical energy delivered to anywhere along the grid to re-power trucks coursing across the nation's highways charged by “plug-in” electrical method or by direct-heat transfer using re-circulating gas between stationary heat stores and those on the truck. By first weaning long-haul trucks off of high priced diesel, this nation can reduce the need for imported oil by one half.

It is a further purpose of this invention to use the solar-powered grid-feeding concept for re-powering light trucks and SUVs. This nation uses 25% of the world's oil production. By switching to solar-powered grid feeding re-heat for light trucks and SUVs, this nation can produce enough oil to satisfy all domestic needs for automobiles without reducing their size, improving fuel economy and without importing foreign oil.

It is a further purpose of this invention to convert automobiles, SUVs and light trucks to use solar heating as fuel and to make use of truck re-heating infrastructure until more heat transfer stations for automobiles only come on line as backup for automobiles that would otherwise use plug-in electric re-heating for cars in garages and carports.

It is a further purpose of this invention to convert new and used automobiles to operate with solar-powered, grid-feeding electric heating. With conversion to heat-store electric, this nation can once again export most of the oil it produces, making the U.S. the fifth largest exporter of oil behind Iraq.

It is a further purpose of this invention to produce an improved, direct means of collecting solar heating from sun-tracking solar collector to place heat directly into the molecules of heat carrying gas, air, to place heat into storage medium. The concept of passing loose re-circulating gas through the solar collector foci improves the efficiency of solar heating. The loose gas is then sucked back into the heat store after instant heating in the foci takes place in a continuous process. This development makes heat collection from solar radiation a practical, effective and efficient way to place heat into storage for use with large and small, portable and stationary heat-to-electric generators.

It is a further purpose of this invention to use pulse width modulation, PWM, to emulate a sine wave output as an option for direct electric generation to the grid.

It is a further purpose of this invention to use pulse position modulation, PPM, to emulate a sine wave output as an option for direct electric generation to the grid.

For clarity of the disclosure and definition of the claims, the following terms are defined:

“PPM Pulse position modulation” means: Arranging pulses of a uniformly pulsed signal during each period to make the equivalent of an analog sine wave from the arrangement of pulses.

“PWM Pulse width modulation” means: Widening and narrowing signal pulses during each period to make the equivalent of an analog sine wave from the arrangement of different width pulses.

“Generator” means a device for producing electricity.

“Solid state generator” means a device for producing electricity using heat produced flow of holes and electrons.

Thermoelectric” means: A device that operates by the flow of holes and electrons driven by either thermal flow or the flow of current.

“Up-Converter” means: A device for converting high current, low voltage into high voltage moderate current more useful for powering grid service.

“Thermoelectric device” means: A solid state generator or chiller.

“Electrical Loading” means: The electrical loading of industry, institutions, household appliances, lighting, air conditioning, heating, and the power needs for a water well pumping and sanitary sewer in some cases.

“Semiconductor” means: a mixture of one or more elements that has the property of allowing either electrons or holes to move through the mixture depending on whether the mixture has an excess n-type or p-type dopant. The semiconductor nature of thermoelectric wafers is well established in the thermoelectric literature.

“rms” means: Root mean square value of the current and the voltage. For the special case of a sinusoidal current and sinusoidal potential difference, voltage of the same frequency, power is equivalent to the product obtained by multiplying the rms value of the current by the rms value of the potential difference and by the sine of the angular phase difference to determine rms electrical power capacity produced by the generator.

“Zero Cost” means: Solar heating and storage at this time has no cost associated with its use.

“High Mass” means: A dense high temperature material such as ceramic or bauxite fragments that can store very high heat content for long periods of time in high temperature insulation confine.

“Step-Up Transformer” means a large expensive inductive transformer capable of converting low generator voltage into the operating voltage of the utility grid to inject energy into the grid system:

“Grid Feeder” means: A generator that inputs electrical energy into the grid so other applications up or down the line can make use of the energy.

“Three Phase” means: The standard electric power format for grid transmission in the U.S.

“Fin” means: An elongated metal slab with optional tapered ends which are connected on one side to an n-type semiconductor and on the other side to a p-type semiconductor or optionally connected on either side to a conductive wedge.

“Cold fin” means: A fin to be cooled or a fin to be allowed to cool.

“Hot fin” means: A fin that is to be heated.

“Wafer” means: An n-type or p-type semiconductor made in the shape of thin slab where thickness of the shortest dimension is from 1% to 20% of either of the other dimensions.

“Loose Gas Foci Heat Exchanger” means: A heat exchanger that passes gas or air for re-heating through the foci region of a sun-tracking parabolic reflector where heated air is sucked up and the heated gas is delivered to pass through the high density medium in the heat store in re-circulation.

Before describing the methodology for connecting thermoelectric generators to drive the utility grid directly using this invention, figures are provided to illustrate such a working version. Examples are intended to illustrate the basic principles and elements of the device and is in no way intended to limit the scope of the invention as described in the claims.

### BRIEF DESCRIPTION OF DRAWINGS

FIG. 1 illustrates a sun tracking solar parabolic collector and mast that ducts heated air from heat store to pass loose gas through the foci heat exchanger region for re-heat with solar radiation at the parabolic reflector's foci through a coaxial, insulated high temperature conduit.

FIG. 2 illustrates how gas passes through high temperature conduit to deliver and pass gas through region contained in the foci heat exchanger.

FIG. 3 illustrates a heat-to-electric generator with cold and hot sections, blowers and motor and insulated high temperature coaxial duct.

FIG. 4 illustrates a heat-to-electric generator with up-converter, magnetic energy core, transformer secondary winding and high frequency dual switch banks.

FIG. 5 shows larger view of up-converter with two parallel secondary windings, one wound in the opposite direction, output ends of windings tied together, input ends earth-ground through alternate switching MOSfet switches operating at grid frequency.

FIG. 6 illustrates the way two MOSfet switches, connect oppositely wound secondary windings to earth-ground, with current sensing of tied together secondary to produce a high voltage, single phase output to the grid.

FIG. 7 shows an electrical schematic for connecting and using a clock chip as a pulse position modulator, or a pulse width modulator to convert a sine wave signal operating from a grid-connected voltage ladder converting output into a sine wave output for a generator with grid driver output.

FIG. 7 shows an electrical schematic for connecting and using a clock chip as a pulse width modulator, to convert a sine wave signal operating from a grid-connected voltage ladder converting output into a sine wave output for a generator with grid driver output.

FIG. 8 is a chart that illustrates how a sine wave signal picked off voltage ladder is converted into a pulse-width wave form that drives primary switch banks.

FIG. 9 shows a chart that illustrates how a pulse-positioned signal and the polarity switching circuit near earth ground can be keyed to the grid through the resistor ladder to produce a sine wave output for a generator that matches the grid as to phase, wave form and voltage exactly.

FIG. 10 shows how a transmission tower on grid right of way can be fitted with solar-heated stores operating individual generators directly connecting to deliver 345,000 vac to different phases of the grid.

FIG. 11 illustrates a solar-electric installation located on right of way that shows some of the solar-heated stores operating individual generators connecting 345,000 vac generators directly to different phases of the grid and another generator array connecting to transformers of a substation to connect to the grid.

FIG. 12 illustrates a method of grid feeding electrical energy from heat store-generator array at grid voltage into the grid, the grid's energy used to electrically heat a stationary heat store with generator at nighttime, the generator providing electrical power as required for a building during day and nighttime.

FIG. 13 illustrates the way a number of sites in an area can be connected by overhead or underground electrical bus where each site has a heat store and generator system (no heat collector) that can work together or independently.

FIG. 14 illustrates a means of powering different applications in a factory, institution and household, using onsite electrical generation from grid heating for applications.

FIG. 15 illustrates a means of producing solar derived electrical power at one site and delivering this power along the route for grid re-heating of NAFTA trucks traveling between Mexico City and Montreal by both electrical heating and by re-circulation of air, gas, through heat stores.

### DISCLOSURE OF THE INVENTION

To illustrate details of this invention figures are drawn to show components of a few implementations of the invention.

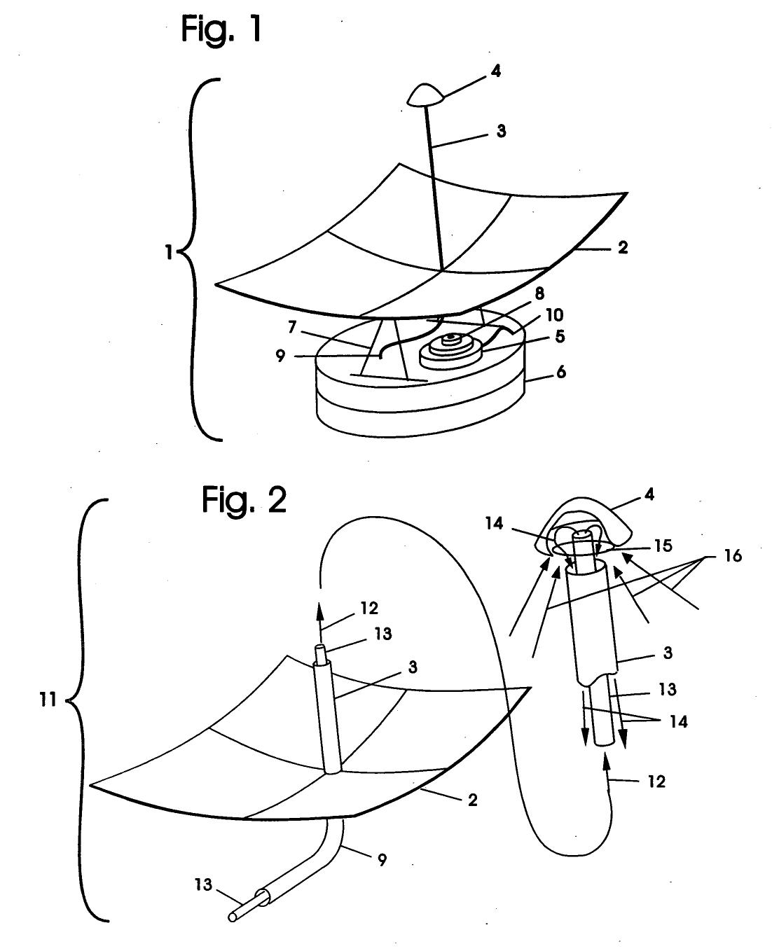

FIG. 1, number 1 illustrates a sun tracking solar parabolic collector 2 with coaxial collector mast 3 that ducts heated air from heat store 6 to pass through loose gas foci heat exchanger 4 for re-heat with solar radiation at the parabolic reflector 2 foci 15 shown in FIG. 2. Heat to power the heat-to electric generator 5 that is mounted to insulated heat store 6 is pulled from the store in a circulation loop separate from hot air flow heat loop through coaxial mast 3. Flexible insulated duct 9 is used to send air to heat store 6 and return heated air to store 6. The collector 2 attaches to heat store 6 with a solar-tracking north star axis oriented mount 7. The generator operates by pulling heated air from the insulated heat store 6, passing this heated air over hot fins of generator 5 with a fan 8, then returning used hot air to heat store 6 in insulated duct 10 which produces electricity from the generator. Fan 8 also draws ambient air through the cold fin side of generator 5, cooling the cold fins of generator 5 wasting the heated cooling air to the atmosphere.

FIG. 2, number 11 illustrates how gas 12 passes through duct 13 by a high temperature blower (not shown) to deliver and pass gas 12 through the foci region 15 contained by foci heated diverter 4, then foci heated gas 14 is sucked down through insulated coaxial mast 3 to transfer solar heated gas 14 to insulated heat store 6 through flexible insulated duct 9. Reflected solar radiation 16 is focused within exchanger region 15 to heat gas 14 quickly and on a molecular basis, which is a vast improvement over the use of metallic-to-gas heat exchangers.

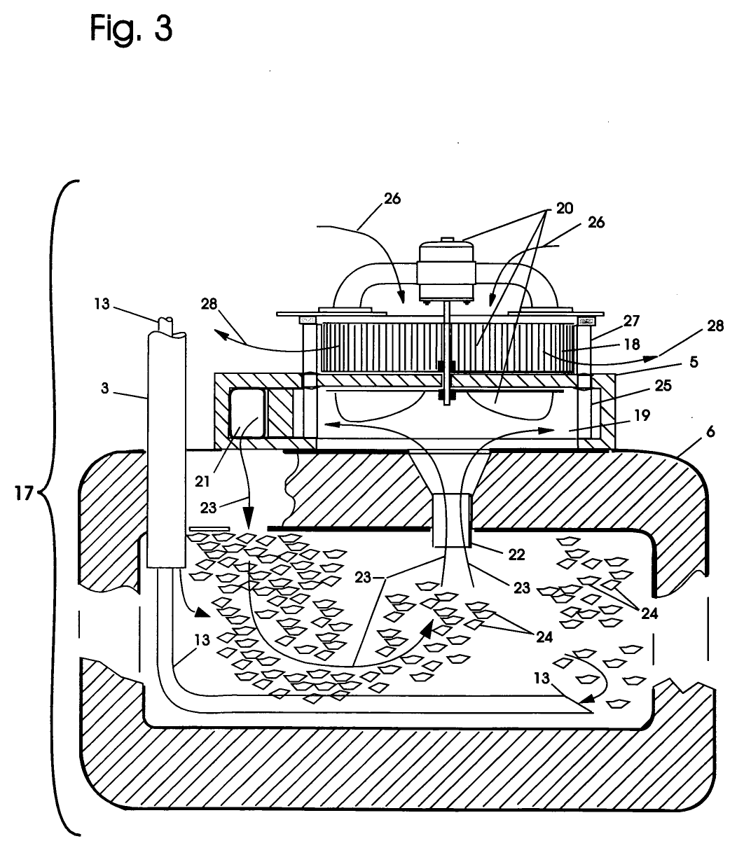

FIG. 3, number 17 illustrates a heat-to-electric generator 5 with a cold section 18 and a hot section 19, blowers and motor 20 and insulated hot section duct 21. Generator 5 is shown mounted on insulated heat store 6 with hot air inlet duct 22 allowing heated air from heat store 6 to enter generator 5 when blowers and motor 20 are operational. Waste heat from generator 5 is returned to heat store 6 using blower and fans 20 through the insulated return duct 21. Hot air 23 moving over solar heated ceramic and bauxite 24 supply the heat, heating the hot fins 25 to operate generator 5. When blowers and motor 20 are energized to draw heated air through duct 22 to heat hot fins 25; the same motor and fans 20 draw ambient cooling air 26 over cold fins 27 to waste heated air 28 to the ambient. In FIG. 3, solar heated air supply from parabolic collector mast 3 is shown entering insulated heat store 6 and coaxial duct 13 is shown sucking air from the heat store.

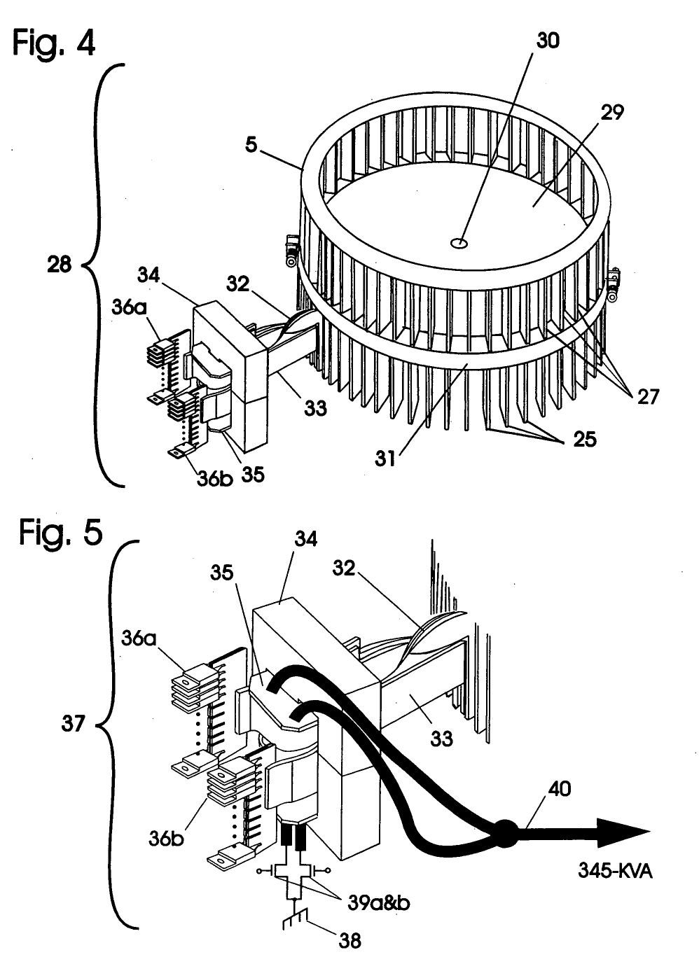

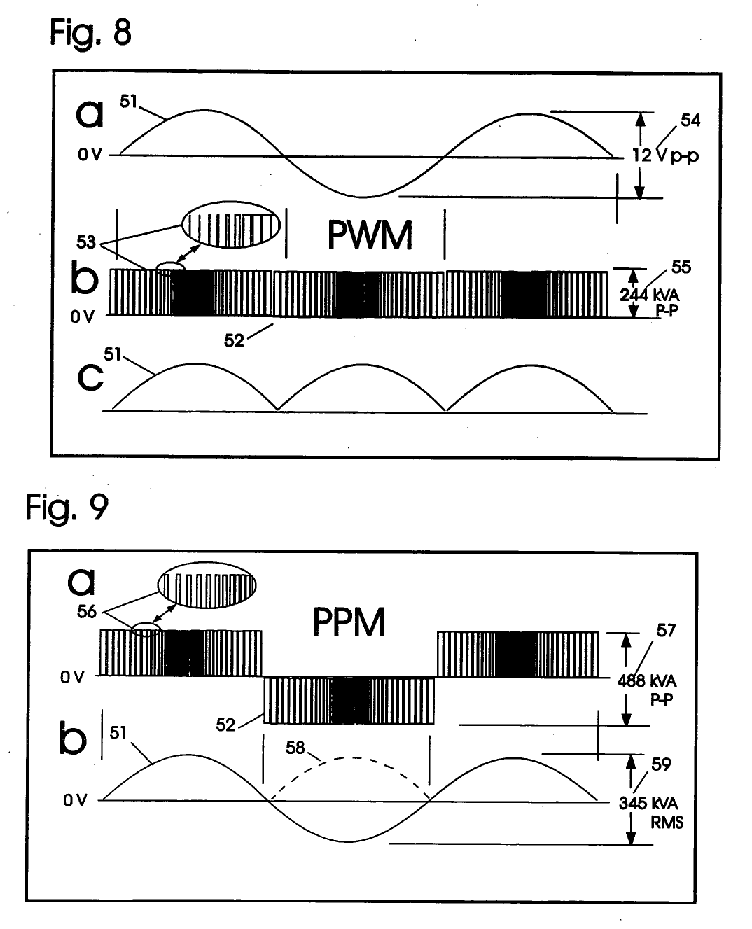

FIG. 4, number 28 illustrates heat-to-electric generator 5 without blowers and motor 20 and hot air return duct. Hot fins 25 and cold fins 27 comprise the heat transfer components of thermoelectric generator 28. Hot-to-cold section separator disk 29 is shown with motor drive shaft hole 30. Generator ring tensioning strap 31 is shown reinforcing the multi-finned structure. Also attached to the ring through bus straps 32 and 33 is the up-converter with magnetic core 34, the transformer secondary winding 35 and high frequency, dual switch banks 36a and 36b. High current circulates around the ring through semiconductor wafers beneath tensioning strap 31 caused by the heating hot fins 25 and cooling of cold fins 27. Conductor bus straps 32 with a twist and 33 with no twist have electrical insulation between them to shunt high circulating current in opposite directions around straps 32 and 33 which are the primary windings of the up-converter. Secondary winding 35 is beneath straps 33 and 32 to complete the function as a transformer. Switch banks between primary twisted straps 32 and 33 cause ring current to flow in opposite directions around the magnetic core 34. Device 28 operates as a heat driven, high current, DC-to-DC power supply, the current around the ring, is in the direction determined by heat flow. Should the ring be shorted at strap ends where straps 32 and 33 tie onto the ring, the shorted current would be tens of thousands of amperes with heat flowing from hot fins to cold fins. Instead, straps 32 and 33 and switch banks 36a and 36b determine the direction of current shunting around the magnetic core 34, current flowing alternately in make-before-break fashion at very high frequency. This creates flux in the magnetic core 34 that induces voltage into the secondary coil 35. The voltage in the secondary can be in the 345,000 volt range if carefully designed. The voltage is also a much higher frequency than is useful on the utility grid and for home use but the output is easily rectified into direct current, DC for further processing as AC. For grid-driving applications, the high frequency output of the generator 5 is easily converted into a 60-Hertz sine wave by either pulse width modulation PWM or pulse position modulation PPM as in FIGS. 8 and 9.

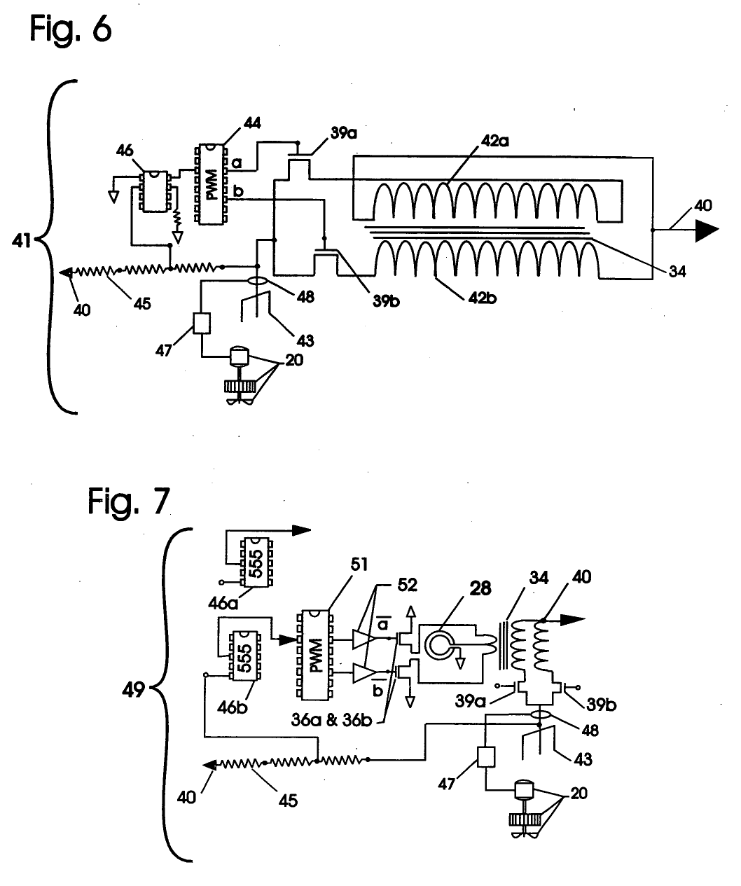

FIG. 5, number 37 shows a larger view of the up-converter portion of 28. Two parallel secondary windings 40, one wound in the opposite direction from the other with the other ends tied to earth-ground 38, through MOSfet switches 39a and 39b that alternately connects the winding ends to earth ground 38. The two parallel opposite windings in the secondary allow a high voltage single-phase, 60-Hertz output from the other ends of tied together windings 40, shown emerging from the other side of secondary coil 35 near MOSfet switches 39a and 39b. Lead 40 will be tied directly to the grid with the other individual ends switched to earth ground alternately at 60-Hz. The voltage out of lead 40 can be any value depending on design, from 220 vac to 354,000 vac, which is one of the values frequently used with utility grids. It will be shown later in FIGS. 6 through 9, how high frequency transformed voltage through the up-converter can result in 60 Hertz power using pulse width modulation, PWM or pulse position modulation, PPM switching methods using Mosfet switches 39a and 39b to realize a 60 Hertz alternating current, AC output suitable for insertion into the grid.

FIG. 6, number 41 illustrates the way two MOSfet switches 39a and 39b are used to alternately connect oppositely wound secondary windings 42a and 42b to earth-ground. Circuit 41 sets the frequency of the generator output 40 by controlling the phase of windings 42a and 42b exactly referenced to the grid based on resistor ladder reference 45, which connects 40 to the grid. Other ends of oppositely wound secondary coils 42a and 42b wound about up-converter magnetic core 34 are tied together to produce a high voltage output 40 connecting directly to the grid. To create a 60-Hertz, single-phase output 40 is grid phased, 39a and 39b switch alternately to connect coils 42a and 42b to either earth ground or open. Switching occurs by pulling down normally high pin of PWM 44. PWM chip 44 alternates between driving an a-drive and b-drive of PWM 44 at 60-Hertz. The switch change-over is made at zero voltage crossing of the grid determined by opto-isolator 46 turning “on” when voltage across ladder 45 becomes positive and turning off when ladder tap crosses zero to become negative. This way, opto-isolator chip 46 controls PWM chip 44 using grid reference 45 to drive MOSfet chips 39a and 39b exactly in phase with the 60-Hertz of the grid. Power output from the generator 5 is by speed of blower motor 20 in FIG. 6 and speed controller 47. The motor and blowers 20 brings in heat from the heat store 6 to pass over the hot fins of the generator and likewise bringing in cooling air to cool cold fins. Once the generator is operating with output at grid voltage, with the output already connected to the grid, the speed of blowers and motor 20 is increased under the control of speed controller 47 and Rogowski current sensor and integrator 48 in the earth ground leg of the secondary winding to control the electrical power delivered to the grid at a preset level. Revenue from generator operation is determined from current measured by Rogowski current sensor and integrator 48 and the voltage of the grid at 40. By summing currents for all generators operating single phase and using grid voltage as a multiplier over time, the amount of power injected into the grid is determined. It is a common practice for the grid operator to provide a small step-down transformer, called a TP, that delivers 120 vac as a grid reference for a generator. The 120 vac can be easily transformed down to 12 vac and rectified to DC. This is convenient because 12 vdc can be used as a power supply to drive the generator logic, the 12 vac used to sense grid phase, without ladder 45, and the 12 vdc used to operate chips 44, 46 which drive MOSfet 39a and 39b. The opto-isolator 44 serves as a zero-voltage crossing detector to change phase to exactly match the grid.

FIG. 7, number 49 shows an electrical schematic for connecting a 555 universal clock chip 46a&b wired either as a pulse width modulator PWM, 46a, or a pulse position modulator PPM, 46b, to create a sine wave signal emulating a grid-connected voltage ladder into either a PWM or a PPM sine wave output for grid generator's up-converter primary output. MOSfet drivers 36a and 36b operate switch banks in the primary side of the up-converter driving primary windings in the up-converter to produce a sine wave out put from the generator's secondary winding. Switch banks produce this output as a string of half-sine wave humps either as PWM or PPM as in FIG. 8c. Circuit 41 in FIG. 6 inverts alternate humps of the secondary output wave form in phase with the 60-Hertz grid to realize a true sine wave secondary output at grid voltage. The unique aspect of this circuit is; the primary up-converter circuit produces the sine wave form, although as a string of voltage humps and the circuit 41 on the secondary side of the up-converter positions alternate humps to form a correct sine wave output for the generator. Another unique aspect of the generator circuit is; the switching and current measuring system is performed in close proximity to earth ground. This feature allows the use of conventional low voltage switching, operating with 12 volts logic driving 12-volt switches to realize the corrected output waveform. It is difficult if not impossible to perform switch corrections using solid state devices at the 345,000 volt, rms level for the grid. The minute amount of power needed to operate the generator circuit can be stolen from the grid either through ladder 45 or through the TP. Also, when the grid is down the generator is also down because of a loss of power, preventing harm to repair workers in this way.

FIG. 8 shows a chart that illustrates how a 12 volt peak-to-peak sine wave signal 51, picked off voltage ladder 45 which is connected between grid and earth ground in FIG. 6a. Signal is converted into a pulse-width modulated waveform 53 in FIG. 8b that drives switch banks 36a and 36b in FIG. 5. To create the negative part of the waveform 51, this is accomplished by switching polarity between windings 42a and 42b in FIG. 6 by pulse width modulator 44, driving switches 39a and 39b which is also synchronized using voltage ladder 45 in FIG. 6. AC voltage output 55 in FIG. 8b results from selection of thousands of turns, one oppositely wound, in the dual secondary of up-converter secondary 35 in FIG. 5.

FIG. 9a shows a chart that illustrates how a pulse-positioned signals 56 are arranged to realize components of a sine wave, and how half of these waveform components are alternately flipped in polarity by the switching circuit of FIG. 6 to create a perfect sine wave as in FIG. 9b. This switching is keyed to the grid through voltage ladder 45, which is referenced to invert portions of the waveform 56 to produce a sine wave output 59, at 345 kva, rms 59. FIG. 9b, 58 shows with dotted line how wave form would look without inverting circuitry of FIG. 6. The output of generator 5 matches the grid for phase, wave form and voltage exactly. Voltage to the grid can be processed at any value, 220 vac up to 345 kva for direct connection to the grid. Output voltage can also be configured to connect to a step-up substation transformer at rated voltage.

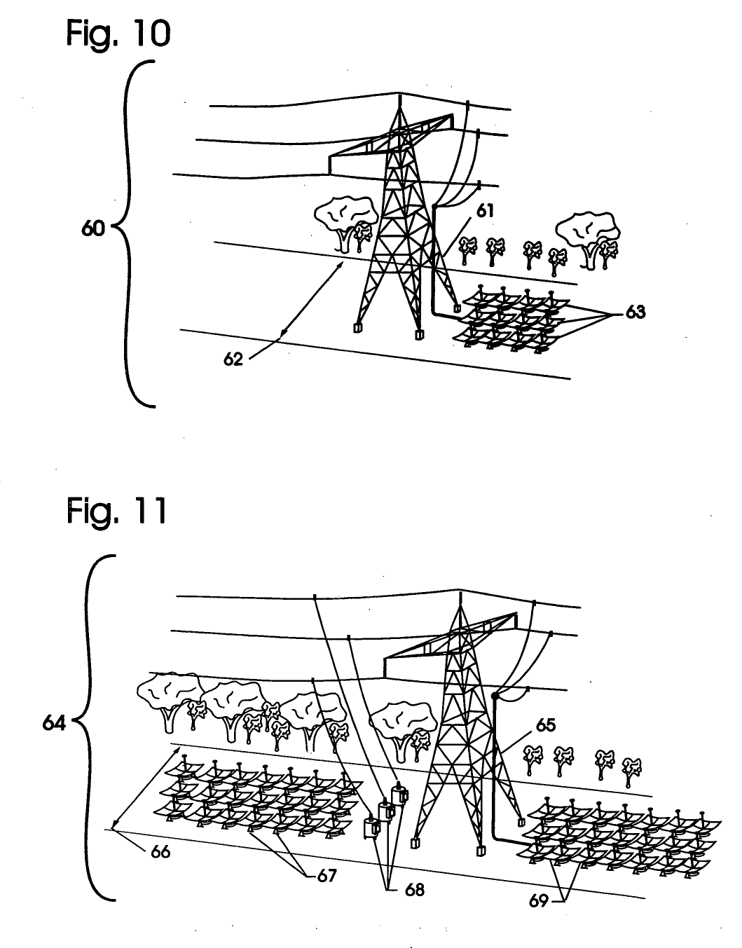

FIG. 10, number 60 shows how a transmission tower 61 on right of way 62 can be fitted with solar-heated stores operating individual generators 63 directly connecting to deliver at grid voltage power 345,000 vac to the different phases of the grid.

FIG. 11, number 64 illustrates a solar-electric installation 67 located beneath the transmission wires held by tower 65 on the right of way 66 that uses substation transformers 68 to increase voltage to connect to the grid near transmission tower 65. Direct grid driving solar-electric generators 69 are also shown for comparison directly connecting to the grid without a need for transformers 68.

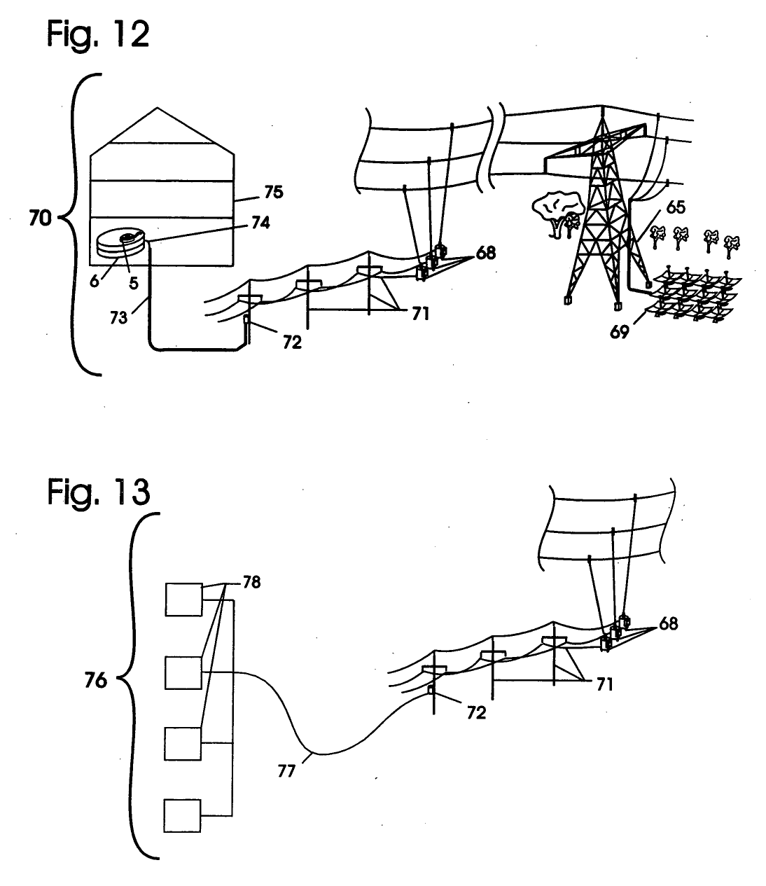

FIG. 12, number 70 illustrates a method of feeding electrical energy from heat-store driven 69 electric generators at grid voltage feeding the grid through tower 65. A portion of the electrical energy is supplied to specific customer's factory 75 through low voltage distribution lines 71 and a further step-down customer transformer 72 using energy from the grid to heat a store 6 by heating cartridges within store 6, not shown, and operating as needed a heat-to-electric generator 5 supplying factory 75 with electricity as needed without a need for onsite solar heat collection. Underground cable 73 connects customer transformer 72 with heat store 6 using connection 74 to cartridge heaters in store 6. Substation transformers 68 step grid voltage down before transferring grid energy onto local electrical distribution 71. Heat store 6 and heat-to-electric generator 5 produces electricity for plant 75 even when the grid is in brownout or blackout conditions. During these times, system 5 and 6 can feed surplus electrical energy not needed by factory 75 back into the grid as needed through transformer 72, distribution lines 71 and transformers 68 to the grid. Other plants in the neighborhood, factories, institutions and households with this same equipment can also hold the grid up and operational until overloading decreases and energy demands become normal.

FIG. 13, number 76 illustrates the way a number of sites 78 in an area can be connected by overhead or underground electrical bus 77 where each site 78 has a heat store 6 and generator 5 system that can work together or independently and off the grid to provide a more reliable power system for factory, institution and households and can give back electrical energy to the grid in times of heavy loading. This capability allows the user to purchase and use power from the utility grid at off peak times to realize a lower price for electricity. If the user has a financial interest in the heat-to-electric generation system that injects electricity directly into the grid, there may be further benefits for the user such as an ultra low rate for investors and an income from the electricity sold to the grid for others to use. Generators of this invention are equipped with a means of controlling these generators to emulate exactly as to phase, waveform, quality and voltage of each phase they support. Generators equipped with a way to insert electricity into the grid have a communication link under control of the grid control agency. This feature provides an automatic way to lock out all generators, preventing them from inserting energy into the grid during maintenance and during times when extra energy is not needed on the grid.

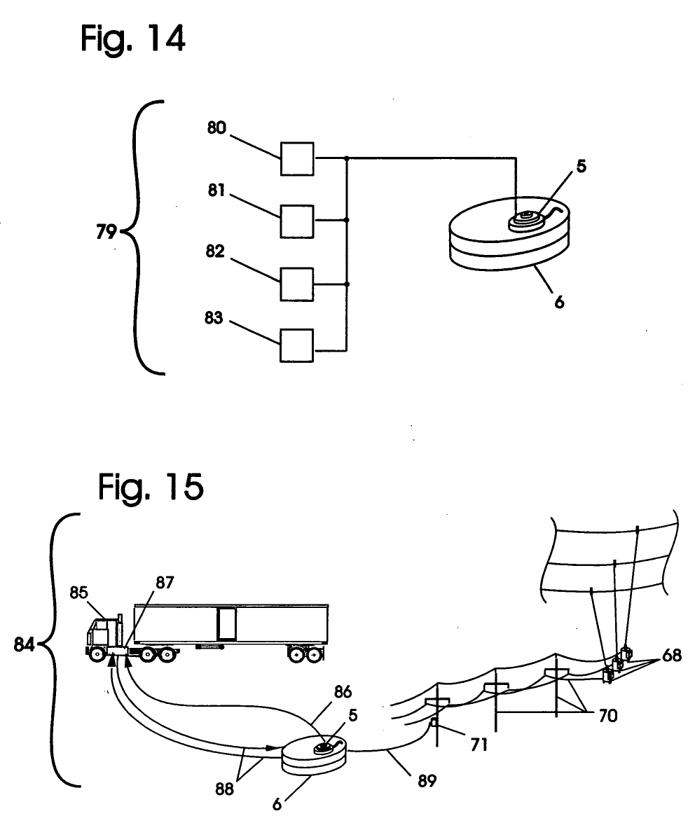

FIG. 14, number 79 illustrates a way to power different applications in a factory, institution and household, using onsite electrical generation for applications such as the lighting 80, HVAC 81, extraction of carbon dioxide, oxygen, nitrogen 82, nighttime atmospheric fresh water harvesting 83 and numerous other factory and institution specific applications. By using the grid only at nighttime to charge the heat store 6 as needed, lower electrical rates can be realized. By having a sufficient supply of stored heat, systems 5, 6 can be called on by utility to shoulder the grid during overloading. Heat stores serve as a reliable battery for the grid allowing large stationary power plants to run at their optimum efficiency calling on as many of the 5,6 systems to help out as needed to supply any power deficits, and heat-storage serves as an electric storage means for later use.

FIG. 15, number 84 illustrates a means of producing solar-derived electrical power, delivering this power for the re-heating of NAFTA trucks traveling between Mexico City and Montreal. Over-the-road trucks can be easily refitted to replace the diesel drive train to use an onboard-the-truck electric drive train and store of the 5, 6 type of FIG. 14. While re-fitted trucks are normally fitted with heat stores to give them a 3,000 mile range, trucks will also need re-heating stations. Truck stops that do not take advantage of solar-to-electric generation on site, can make use of the grid transformers 68 to re-power truck 85 at truck stops across the nation. A heat store 6 and heat-to-electric generator 5 onboard truck 85 can be re-energize in about half an hour by supplying electricity 86 to power cartridge heaters in the truck's store 87. Another method of re-heating involves hot air exchanged between heat store 6 and truck store 87 to quickly bring the truck's heat store up to cross country temperatures. The truck stop can avoid having to purchase electrical energy from the grid, by removing grid link 89 after the truck stop installs an array of solar collector systems FIG. 1, 1. Truck drivers can then purchase cheap sunshine, converted into electricity or energy transferred as re-circulated, heated air into onboard stores. This will eliminate entirely the need to purchase expensive diesel or using high priced electricity from the grid for heating.

Thus having described with figures and text a novel method of connecting a number of small heat-to-electric generators connected directly to the utility grid, and a means of controlling these generators to emulate exactly as to phase, wave form, quality and voltage of each phase they support, a way to insert electricity into the grid under control of the grid control agency, an automatic way to lock out all generators, preventing them from inserting energy into the grid during maintenance, a way to synchronize frequency and wave form in the generator for precise insertion, and a way to collect and store solar heat to make electricity for the grid and to power other offsite facilities with and without solar collection capability and to power a broad range of useful products for home, industry and institutions, and a way to eliminate the need for diesel in transportation, we claim:

We claim:

1. A solar power station comprising:
A. at least one sunlight concentrating parabolic reflector that focuses sunlight on a target, and
B. an insulated heat store consisting of high density solid particles, and
C. a means to transfer energy from said target to said heat store, and
D. a means to transfer energy from said heat store to hot fins of a thermoelectric generator, and
E. a control circuit comprising:
(i) a resistance ladder connected to an electric company high voltage grid, and
(ii) a takeoff from said resistance ladder connected as an input to a grounded opto isolator, and
(iii) an output from said opto isolator connected to ground through a resistor and an output connected to the normally held high input of a pulse width modulator used as a switch, and
(iv) two outputs of said pulse width modulator each connected to one or the other bank of high frequency parallel MOSfet switches that control the output of the secondary of said thermoelectric generator to realize a sine wave for input to the grid, and
(v) a Rogowski current sensor and integrator that controls the speed of a motor that moves air from said heat store to the hot fins of said thermoelectric generator, and
(vi) a universal clock chip also connected to said resistance ladder the output of which connects to a second high frequency pulse-width modulator switch, and
(vii) the output of said second high frequency pulse-width modulator that has two connections one each to inverted MOSfet drivers that control said high frequency MOSfet switch banks allowing a primary circuit to correct sine wave form in secondary output of generator, and
(viii) a means to turn on and off the output of said thermoelectric generator.

2. A power station according to claim 1 further comprising an AC transformer connecting the output of one or more of said thermoelectric generators to the grid.

3. A power station according to claim 1 comprising a plurality of power station units wherein the outputs of several thermoelectric generators are combined as a Y connection to earth ground before being connected to said grid.

4. A power station according to claim 1 wherein said primary 555 controller output connects to a pulse position modulator chip to realize sine wave secondary output.

5. A power station according to claim 1 wherein said primary 555 controller output connects to a pulse width modulator chip to realize a sine wave primary input to MOSfet switch banks and secondary sine wave output.

6. A power station according to claim 1 wherein generator current output to grid is sensed metered and measured with Rogowski coil and integrator located around ground leg.

7. A power station according to claim 1 wherein said target is a loose air foci heating of air re-circulated through insulated coaxial lines by high temperature air blower between said target and said heat store.

8. A power station according to claim 5 wherein said blower derives electrical energy from the output of said generator.

9. A power station according to claim 1 wherein said thermoelectric generator is positioned adjacent to said heat store to allow hot air to circulate between said heat store and hot fins of said thermoelectric generator.

10. A power station according to claim 1 wherein said thermoelectric generator utilizes n-type selenium doped bismuth telluride and p-type bismuth dope antimony telluride.

11. A power station according to claim 1 wherein said parabolic collector is a solar tracking circular mirror and said target is fixed at the focal point of said mirror.

12. A power station according to claim 1 wherein said target is a quartz tube with a reflective mirror on the opposite side from said parabolic collector.

13. A power station according to claim 1 wherein said high density solid particles are made of ceramic material.

14. A power station according to claim 1 wherein said high density solid particles are made of bauxite.

15. A power station according to claim 1 wherein multiple power station units are connected to one of three separate outputs one of each of said three outputs is connected to one each of power station grid three phase lines.

16. A power station according to claim 1 further comprising a means to heat said heat store using energy from combustion.

17. A claim according to claim 16 wherein said means to heat said heat store is a fuel combustor connected to said heat store by forced air transferred using insulated tubes from said fuel combustor to said heat store using a speed controlled fan.

18. A gas powered power station comprising:
A. at least one thermoelectric generator
B. an insulated heat store consisting of high density solid particles, and
C. a means to transfer energy from said gas power to said heat store, and
D. a means to transfer energy from said heat store to hot fins of a thermoelectric generator, and
E. a control circuit comprising:
(i) a resistance ladder connected to an electric company high voltage grid, and
(ii) a takeoff from said resistance ladder connected as an input to a grounded opto isolator, and
(iii) an output from said opto isolator connected to ground through a resistor and an output connected to the normally held high input of a pulse width modulator used as a switch, and
(iv) two outputs of said pulse width modulator each connected to one or the other bank of high frequency parallel MOSfet switches that control the output of the secondary of said thermoelectric generator to realize a sine wave for input to the grid, and
(v) a Rogowski current sensor and integrator that controls the speed of a motor that moves air from said heat store to the hot fins of said thermoelectric generator, and
(vi) a universal clock chip also connected to said resistance ladder the output of which connects to a second high frequency pulse-width modulator switch, and
(vii) the output of said second high frequency pulse-width modulator that has two connections one each to inverted MOSfet drivers that control said high frequency MOSfet switch banks allowing a primary circuit to correct sine wave form in secondary output of generator

19. An electricity storage station comprising:
A. an insulated heat store containing high density particles of greater than 3 grams per cubic centimeter and having a resistance heating element inside, and
B. an electrical connection from the grid of an electric company to said resistance heating element of said heat store, and
C. a means to turn on and off said connection from said electric company grid to said resistance element, and
D. a thermoelectric generator connected to said heat store that converts heat energy stored in said heat store to electricity and wherein said thermoelectric generator connects its output directly back to said grid as described in claim 1, and
E. a means to control the output of said thermoelectric generator.

20. An electricity storage station according to claim 19 wherein said means to turn on and off said connection from said grid to said heat store is an electronically controlled switch.

21. An electricity storage station according to claim 19 wherein said means to control the output of said thermoelectric generator is a switch that turns on or off the fan the moves air from said heat store to said thermoelectric generator.

22. An electricity storage station according to claim 21 wherein said switch is remotely controlled.
